(19) United States
(12) Patent Application Publication
(10) Pub. No.: US 2026/0090354 A1
(43) Pub. Date: Mar. 26, 2026

(54) SEMICONDUCTOR STRUCTURE AND MANUFACTURING METHOD THEREFOR

(71) Applicant: CXMT Corporation, Hefei City (CN)

(72) Inventor: Shuangshuang WU, Hefei City (CN)

(73) Assignee: CXMT Corporation, Hefei City (CN)

(21) Appl. No.: 19/402,605

(22) Filed: Nov. 26, 2025

Related U.S. Application Data
(63) Continuation of application No. PCT/CN2025/115530, filed on Aug. 19, 2025.

(30) Foreign Application Priority Data
Sep. 26, 2024 (CN) 202411359347.5

(51) Int. Cl. H10W 20/20

(52) U.S. Cl. CPC H10W 20/2134; H10W 20/0249

(57) ABSTRACT

The semiconductor structure includes: a substrate; a first insulating dielectric layer disposed on the substrate; a front layer structure disposed in the first insulating dielectric layer; a second insulating dielectric layer disposed on the first insulating dielectric layer; a third insulating dielectric layer disposed on the second insulating dielectric layer; a current layer structure disposed in the third insulating dielectric layer, including a plurality of first conductive wires spaced apart from each other; a first interconnection structure passing through the second insulating dielectric layer to connect a portion of the first conductive wires and the front layer structure; and a second interconnection structure passing through the first insulating dielectric layer and the second insulating dielectric layer to connect a portion of the first conductive wires, the first interconnection structure and the second interconnection structure being isolated from each other.

### CROSS-REFERENCE TO RELATED APPLICATIONS

This application is a continuation of International Patent Application No. PCT/CN2025/115530 filed on Aug. 19, 2025, which claims priority to Chinese Patent Application No. 202411359347.5 filed on Sep. 26, 2024. The disclosures of the above-referenced applications are hereby incorporated by reference in their entirety.

### TECHNICAL FIELD

Embodiments of the present disclosure relate to the field of semiconductors, and in particular to a semiconductor structure and a manufacturing method therefor.

### BACKGROUND

Memories are memory components for storing programs and various types of data information. A random access memory (random access memory, RAM) used for a computer system may be classified into a dynamic random access memory (dynamic random access memory, DRAM) and a static random-access memory (static random-access memory, SRAM), and the DRAM is a semiconductor memory device commonly used in a computer and is composed of a plurality of repetitive memory cells.

At present, there is a need to improve the reliability of the semiconductor structure.

### SUMMARY

The embodiments of the present disclosure provide a semiconductor structure and a manufacturing method therefor, which can at least improve the reliability of the semiconductor structure.

According to some embodiments of the present disclosure, in one aspect, the embodiments of the present disclosure provide a semiconductor structure. The semiconductor structure includes: a substrate, where a first insulating dielectric layer is disposed on the substrate; a front layer structure, where the front layer structure is disposed on the first insulating dielectric layer; a second insulating dielectric layer, where the second insulating dielectric layer is disposed on the first insulating dielectric layer; a third insulating dielectric layer, where the third insulating dielectric layer is disposed on the second insulating dielectric layer; a current layer structure, where the current layer structure is disposed in the third insulating dielectric layer and includes a plurality of first conductive wires spaced apart from each other; a first interconnection structure, where the first interconnection structure passes through the second insulating dielectric layer and is connected to a portion of the plurality of first conductive wires and the front layer structure; and a second interconnection structure, where the second interconnection structure passes through the first insulating dielectric layer and the second insulating dielectric layer and is connected to a portion of the first conductive wires. The first interconnection structure and the second interconnection structure are isolated from each other.

According to some embodiments of the present disclosure, in another aspect, the embodiments of the present disclosure further provide a method for manufacturing a semiconductor structure. The method for manufacturing a semiconductor structure includes: providing a substrate, where a first insulating dielectric layer is disposed on the substrate; forming a front layer structure, where the front layer structure is disposed on the first insulating dielectric layer; forming a second insulating dielectric layer, where the second insulating dielectric layer is disposed on the first insulating dielectric layer; forming a third insulating dielectric layer, where the third insulating dielectric layer is disposed on the second insulating dielectric layer; forming a current layer structure, where the current layer structure is disposed in the third insulating dielectric layer and includes a plurality of first conductive wires spaced apart from each other; forming a first interconnection structure, where the first interconnection structure passes through the second insulating dielectric layer to connect a portion of the plurality of first conductive wires and the front layer structure; and forming a second interconnection structure, where the second interconnection structure passes through the first insulating dielectric layer and the second insulating dielectric layer to connect a portion of the first conductive wires. The first insulating dielectric layer and the second insulating dielectric layer are isolated from each other.

### BRIEF DESCRIPTION OF DRAWINGS

One or more embodiments are exemplarily illustrated with reference to figures in the corresponding drawings, and these exemplary illustrations are not to be construed as limiting the embodiments. Unless expressly stated otherwise, the figures in the drawings do not constitute a limitation of scale. To more clearly illustrate the technical solutions in the embodiments of the present disclosure or conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIGS. 1 to 4 are schematic structural diagrams of a semiconductor structure according to an embodiment of the present disclosure;

FIG. 5 is a flowchart of a method for manufacturing a semiconductor structure according to an embodiment of the present disclosure; and

FIGS. 6 to 18 are schematic structural diagrams corresponding to various steps in a method for manufacturing a semiconductor structure according to an embodiment of the present disclosure.

### DESCRIPTION OF EMBODIMENTS

As is known from the background, the reliability of the semiconductor structure needs to be improved.

The embodiments of the present disclosure are described in detail hereinafter with reference to the drawings. However, those of ordinary skill in the art can understand that, in the embodiments of the present disclosure, numerous technical details are set forth to enable readers to better understand the present disclosure. However, the technical solutions claimed by the present disclosure can also be implemented even without these technical details and the various changes and modifications based on the following embodiments.

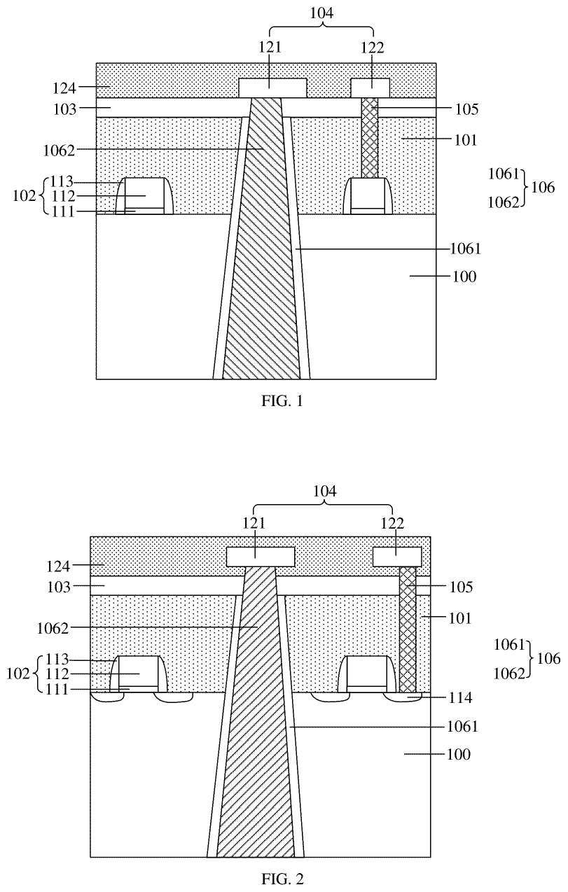

Referring to FIGS. 1 and 2, FIG. 1 is a schematic structural diagram of a semiconductor structure according to an embodiment of the present disclosure, and FIG. 2 is a schematic structural diagram of a semiconductor structure according to some other embodiments of the present disclosure.

In some embodiments, the semiconductor structure includes: a substrate 100; a first insulating dielectric layer 101 is disposed on the substrate 100.

The semiconductor structure further includes: a front layer structure 102; the front layer structure 102 is disposed in the first insulating dielectric layer 101.

The semiconductor structure further includes: a second insulating dielectric layer 103; the second insulating dielectric layer 103 is disposed on the first insulating dielectric layer 101.

The semiconductor structure further includes: a third insulating dielectric layer 124; the third insulating dielectric layer 124 is disposed on the second insulating dielectric layer 103.

The semiconductor structure further includes: a current layer structure 104; the current layer structure 104 includes a plurality of first conductive wires spaced apart from each other, for example, a first conductive wire 121 and a first conductive wire 122 spaced apart from each other by means of the third insulating dielectric layer 124.

The semiconductor structure further includes: a first interconnection structure 105; the first interconnection structure 105 passes through the second insulating dielectric layer 103 and is connected to the first conductive wire 122 and the front layer structure 102.

The semiconductor structure further includes: a second interconnection structure 106; the second interconnection structure 106 passes through the first insulating dielectric layer 101 and the second insulating dielectric layer 103 and is connected to the first conductive wire 121, and the first interconnection structure 105 and the second interconnection structure 106 are isolated from each other.

The semiconductor structure provided in the embodiments of the present disclosure includes the first interconnection structure connecting the front layer structure and the current layer structure and the second interconnection structure leading out the current layer structure. The combination of insulating layers composed of the second insulating dielectric layer and the first insulating dielectric layer prevents the presence of undesired conductive paths between the interconnection structures and between the interconnection structure and the front layer structure, thus avoiding negative impacts on the performance and reliability of the device.

In some embodiments, a material of the substrate 100 may include a semiconductor material, for example, including but not limited to silicon. In some embodiments, the material of the substrate 100 may include silicon, germanium, silicon germanium, or the like; in some embodiments, the material of the substrate 100 further includes silicon carbide, gallium arsenide, gallium phosphide, indium phosphide, indium arsenide, indium antimonide, or the like; in some embodiments, the material of the substrate 100 may further include gallium arsenide phosphide, gallium indium phosphide, gallium indium arsenide, indium gallium arsenide phosphide, aluminum indium arsenide, and/or aluminum gallium arsenide. In some embodiments, the substrate 100 may also be a silicon-on-insulator structure.

In addition, the substrate 100 may be doped according to design requirements (e.g., a P-type substrate or an N-type substrate). In some embodiments, the substrate 100 may be doped with P-type doping ions (e.g., boron ions or aluminum ions) or N-type doping ions (e.g., phosphorus ions or arsenic ions).

In some embodiments, the first insulating dielectric layer 101 may be a single-layer structure formed by an insulating material, or may be a multi-layer structure formed by depositing an insulating material multiple times, for example, a composite film layer composed of multiple layers of silicon dioxide, or may be a multi-layer structure formed by composite deposition of different insulating materials, for example, a composite film layer composed of at least two of silicon dioxide, silicon nitride, silicon oxynitride, silicon carbonitride, or other insulating dielectric materials.

In some embodiments, the front layer structures 102 may be transistors or other semiconductor devices. In the embodiments of the present disclosure, the front layer structure 102 is taken as a transistor by way of example, but this does not constitute a limitation on the type of the front layer structure 102. When the front layer structure 102 is a transistor, FIG. 1 shows a simple schematic diagram of the front layer structure 102, and the front layer structure includes a gate oxide layer 111 located on the substrate 100, a gate 112 disposed on the gate oxide layer 111, and an isolation dielectric layer 113 covering outer sides of the gate oxide layer 111 and the gate 112. The gate 112 may be a single-layer structure or a multi-layer structure, and the isolation dielectric layer 113 may be a single-layer structure or a multi-layer structure. The isolation dielectric layer 113 and the first insulating dielectric layer may include the same insulating material or different insulating materials.

In some embodiments, the second insulating dielectric layer 103 and the first insulating dielectric layer 101 include different insulating materials. In some embodiments, when the first insulating dielectric layer 101 is a multi-layer structure, a material of a portion of the first insulating dielectric layer 101 disposed adjacent to the second insulating dielectric layer 103 is different from a material of the second insulating dielectric layer 103. For example, the first insulating dielectric layer 101 includes silicon dioxide, and the second insulating dielectric layer 103 includes silicon nitride.

In some embodiments, the third insulating dielectric layer 124 includes a material different from that of the second insulating dielectric layer 103. For example, the third insulating dielectric layer 124 is made of silicon dioxide, and the second insulating dielectric layer 103 is made of silicon nitride.

In some embodiments, the current layer structure 104 is a metal conductive line, such as a copper conductive line or a tungsten conductive line. A barrier layer for preventing diffusion of the metal conductive line, such as tantalum (Ta), tantalum nitride (TaN), and cobalt (Co), is further provided between the current layer structure 104 and the third insulating dielectric layer 124.

It should be noted that the front layer structure and the current layer structure in the embodiments of the present disclosure do not constitute a limitation on the structure itself. In some embodiments, the front layer structure and the current layer structure are used to indicate a positional relationship or a forming sequence of the two structures. For example, for the current layer structure, the front layer structure indicates that the front layer structure is formed before the current layer structure, or in terms of the positional relationship, the front layer structure is closer to the substrate.

In some embodiments, the first interconnection structure 105 and the second interconnection structure 106 include different metal materials. For example, the first interconnection structure includes an interconnection structure composed of metal tungsten or an alloy thereof, and the second interconnection structure 106 includes an interconnection structure composed of metal copper or an alloy thereof.

In some embodiments, the first interconnection structure 105 and the second interconnection structure 106 are isolated from each other by means of the first insulating dielectric layer 101 and the second insulating dielectric layer 103. The stress between the first interconnection structure 105 and the second interconnection structure 106 is alleviated by means of the first insulating dielectric layer 101 and the second insulating dielectric layer 103, thereby improving the reliability of the semiconductor structure.

In some embodiments, the second interconnection structure 106 may be a through silicon via (TSV); that is, the second interconnection structure 106 penetrates through the substrate 100 and is in contact connection with the first conductive wire 121. By configuring the second interconnection structure 106 to penetrate through the substrate 100 and be in contact connection with the first conductive wire 121, it is beneficial for providing a signal to the second interconnection structure 106 from the other end, distal to the front layer structure 102, of the substrate 100, thereby facilitating the transmission of the signal to the first conductive wire 121, or facilitating the output of the signal within the first conductive wire 121.

With continued reference to FIG. 1, in some embodiments, the first conductive wire 121 and the first conductive wire 122 cover a top surface of the second insulating dielectric layer 103, and the first interconnection structure 105 further passes through the first insulating dielectric layer 101 and is connected to the front layer structure 102.

With continued reference to FIG. 2, in some other embodiments, the first interconnection structure 105 and the second interconnection structure 106 further pass through the third insulating dielectric layer 124 and are respectively connected to the first conductive wire 121 and the first conductive wire 122.

In some embodiments, as shown in FIG. 1, the first interconnection structure 105 is connected to the gate 112 of the front layer structure 102, which achieves the connection between the first conductive wire 122 and the front layer structure 102.

In some embodiments, as shown in FIG. 2, the front layer structure 102 further includes a connection end 114, such as a source or a drain, disposed in the substrate 100, and the first interconnection structure 105 is connected to the connection end 114, thereby achieving the connection between the first conductive wire 122 and the front layer structure 102.

In some embodiments, as shown in FIGS. 1 and 2, a plurality of front layer structures 102 are provided, and the second interconnection structure 106 may be located in the first insulating dielectric layer 101 between two adjacent front layer structures 102.

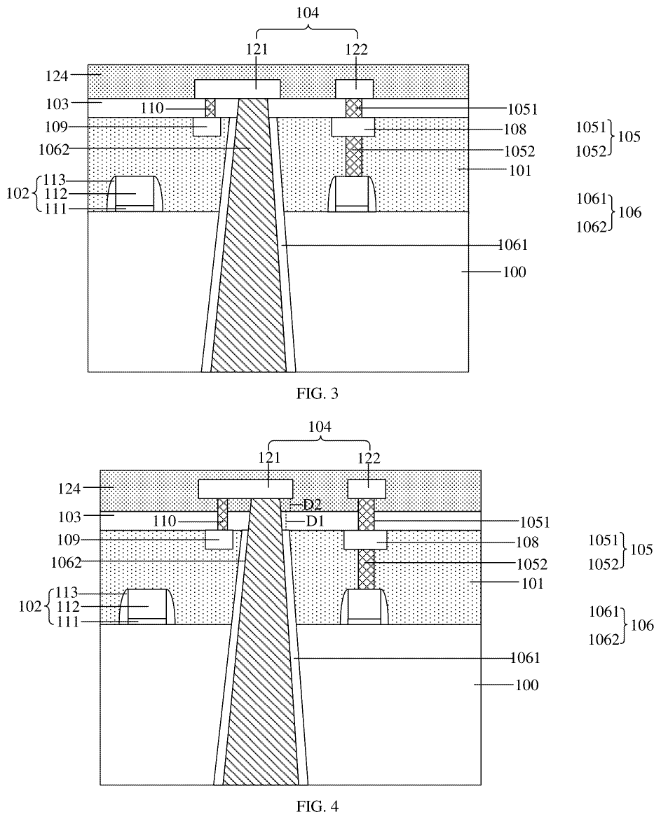

With continued reference to FIG. 3, FIG. 3 is a schematic structural diagram of a semiconductor structure according to an embodiment of the present disclosure. In some embodiments, the front layer structure further includes a second conductive wire 108 and a second conductive wire 109 that are located above the transistor 102. The second conductive wire 108 and the second conductive wire 109 are located in the first insulating dielectric layer 101 and are isolated from each other. The first interconnection structure 105 includes a first interconnection portion 1051 connecting the first conductive wire 122 and the second conductive wire 108, and a second interconnection portion 1052 connecting the second conductive wire 108 and the transistor 102. The first interconnection portion 1051 passes through the second insulating dielectric layer 103 and is connected to the second conductive wire 108, and the second interconnection portion 1052 passes through the first insulating dielectric layer 101 and is connected to the transistor 102.

In some embodiments, the first interconnection portion 1051 further passes through a portion of the third insulating dielectric layer 124 and is connected to the first conductive wire 122.

In some embodiments, the first interconnection portion 1051 and the second interconnection portion 1052 may include different metals. For example, the first interconnection portion 1051 includes copper or an alloy thereof, and the second interconnection portion 1052 includes tungsten or an alloy thereof.

In some embodiments, the first interconnection portion 1051 and the first conductive wire 122 may be an integrated structure, thereby reducing the contact resistance between the first interconnection portion 1051 and the first conductive wire 122, and improving the reliability of the connection between the first interconnection portion 1051 and the first conductive wire 122.

In some embodiments, the second interconnection portion 1052 and the second conductive wire 108 may be an integrated structure, thereby reducing the contact resistance between the second interconnection portion 1052 and the second conductive wire 108, and improving the reliability of the connection between the second interconnection portion 1052 and the second conductive wire 108.

In some embodiments, with continued reference to FIG. 3, the semiconductor structure further includes a third interconnection structure 110. The third interconnection structure 110 is connected to the other second conductive wire 109, and the third interconnection structure 110 is connected to the first conductive wire 121, thereby achieving the connection between the second conductive wire 109 and the second interconnection structure 106.

In the embodiments of the present disclosure, by adding the second conductive wire in the front layer structure, the layout of the semiconductor structure can be further compact, transmission channels between conductive wires in each layer are increased, and the signal transmission density is improved.

In some embodiments, the third interconnection structure 110 and the first interconnection portion 1051 are made of the same material. For example, both the third interconnection structure and the first interconnection portion include copper or an alloy thereof. The third interconnection structure 110 and the first interconnection portion 1051 may also include different materials. For example, the first interconnection portion 1051 includes copper or an alloy thereof, and the third interconnection structure 110 includes tungsten or an alloy thereof.

With continued reference to FIGS. 1 to 4, in some embodiments, the second interconnection structure 106 includes an insulating liner layer 1061 and a conductive interconnect layer 1062. The insulating liner layer 1061 is disposed between the first insulating dielectric layer 101 and the conductive interconnect layer 1062, and the insulating liner layer 1061 may isolate the conductive interconnect layer 1062 from the substrate 100, thereby preventing the conductive interconnect layer 1062 from contaminating the first insulating dielectric layer 101 and preventing the conductive interconnect layer 1062 from contaminating the substrate 100.

In some embodiments, the conductive interconnect layer 1062 is disposed in direct contact with the second insulating dielectric layer 103.

In some embodiments, the insulating liner layer 1061 is further disposed between the substrate 100 and the conductive interconnect layer 1062, the conductive interconnect layer 1062 further passes through a portion of the third insulating dielectric layer 124 and is in contact connection with the first conductive wire 121, and the conductive interconnect layer 1062 is disposed in direct contact with the third insulating dielectric layer 124.

With continued reference to FIG. 4, FIG. 4 is a schematic structural diagram of a semiconductor structure according to an embodiment of the present disclosure. In some embodiments, a ratio of a thickness D1 of the first interconnection structure 105 in the second insulating dielectric layer 103 to a thickness D2 of the first interconnection structure in the third insulating dielectric layer 124 is 2:1 to 5:1. It can be understood that when the current layer structure includes the second conductive wire 108 and the second conductive wire 109, the second insulating dielectric layer 103 is disposed on the second conductive wires, such that the thickness of the formed second interconnection structure 106 is larger. Therefore, the isolation between the second interconnection structure 106 and the front layer structure becomes especially important. By configuring the thickness of the second interconnection structure 106 in the second insulating dielectric layer 103 to be greater than the thickness of the second interconnection structure in the third insulating dielectric layer 124, the isolation between the second interconnection structure 106 and the front layer structure is enhanced. However, the larger the thickness of the second insulating dielectric layer 103 is, the higher the difficulty in finally forming the second interconnection structure 106 connected to the first conductive wire 121 is. Therefore, by configuring the ratio of the thickness of the second interconnection structure 106 in the second insulating dielectric layer 103 to the thickness of the second interconnection structure in the third insulating dielectric layer 124 to be 2:1 to 5:1, the protection capability of the second insulating dielectric layer 103 can be obtained while reducing the difficulty in the forming process of the second interconnection structure 106.

The embodiments of the present disclosure further provide a method for manufacturing a semiconductor structure. The method for manufacturing a semiconductor structure may be used to form the semiconductor structure as shown in FIGS. 1 to 4. The method for manufacturing a semiconductor structure provided in the embodiments of the present disclosure is described below with reference to the drawings. It should be noted that for the same or corresponding parts as those in the foregoing embodiments, reference may be made to the corresponding descriptions of the foregoing embodiments, and details are not described below again.

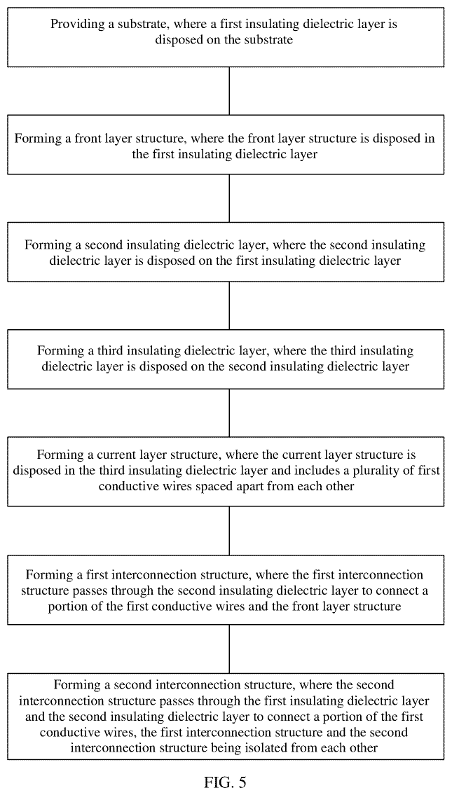

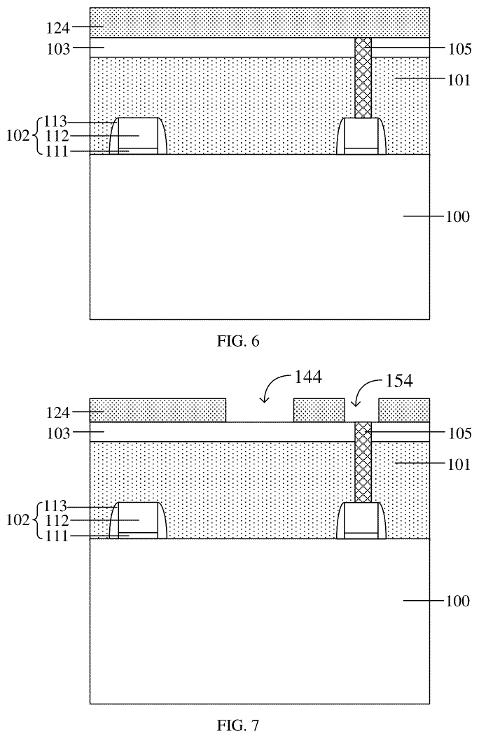

Referring to FIGS. 5 to 18, FIG. 5 is a flowchart of a method for manufacturing a semiconductor structure according to an embodiment of the present disclosure, and FIGS. 6 to 18 are schematic structural diagrams corresponding to various steps in a method for manufacturing a semiconductor structure according to an embodiment of the present disclosure.

Referring to FIG. 5, in some embodiments, a method for manufacturing a semiconductor structure includes: providing a substrate, where a first insulating dielectric layer is disposed on the substrate.

The method for manufacturing a semiconductor structure further includes: forming a front layer structure, where the front layer structure is disposed in the first insulating dielectric layer.

The method for manufacturing a semiconductor structure further includes: forming a second insulating dielectric layer, where the second insulating dielectric layer is disposed on the first insulating dielectric layer.

The method for manufacturing a semiconductor structure further includes: forming a third insulating dielectric layer, where the third insulating dielectric layer is disposed on the second insulating dielectric layer.

The method for manufacturing a semiconductor structure further includes: forming a current layer structure, where the current layer structure includes a plurality of first conductive wires spaced apart from each other, and the plurality of first conductive wires are disposed in the third insulating dielectric layer.

The method for manufacturing a semiconductor structure further includes: forming a first interconnection structure, where the first interconnection structure passes through the second insulating dielectric layer to connect a portion of the first conductive wires and the front layer structure.

The method for manufacturing a semiconductor structure further includes: forming a second interconnection structure, where the second interconnection structure passes through the first insulating dielectric layer and the second insulating dielectric layer and is connected to a first conductive wire. The first interconnection structure and the second interconnection structure are isolated from each other.

The following provides further descriptions with reference to the corresponding drawings.

Referring to FIG. 6, a substrate 100 is provided, and a front layer structure 102 is disposed on the substrate 100. The front layer structure 102 may be a transistor, which includes a gate oxide layer 111 disposed on the substrate 100 and a gate 112 disposed on the gate oxide layer 111. After the gate oxide layer 111 and the gate 112 are formed, an isolation dielectric layer 113 for isolating the gate oxide layer 111 and the gate 112 is formed, the isolation dielectric layer 113 covering side walls of the gate 112 and the gate oxide layer 111.

After the front layer structure 102 is formed, a first insulating dielectric layer 101 covering the front layer structure 102 is formed. The first insulating dielectric layer 101 may be formed by using a thin film deposition process, such as physical vapor deposition (PVD), chemical vapor deposition (CVD), atomic layer deposition (ALD), and epitaxial growth (Epitaxy). The first insulating dielectric layer 101 may be a single-layer film or a multi-layer film structure.

After the first insulating dielectric layer 101 is formed, a second insulating dielectric layer 103 is deposited on the first insulating dielectric layer 101. The second insulating dielectric layer 103 may be formed by using the thin film deposition process, such as PVD, CVD, ALD, and Epitaxy.

After the second insulating dielectric layer 103 is formed, the first insulating dielectric layer 101 and the second insulating dielectric layer 103 are patterned to form a first interconnection structure 105 passing through the second insulating dielectric layer 103 and the first insulating dielectric layer 101. The first insulating dielectric layer 101 and the second insulating dielectric layer 103 are patterned by using a photolithography process in combination with an etching process. The process of etching the first insulating dielectric layer 101 and the second insulating dielectric layer 103 may be dry etching or wet etching.

After the first interconnection structure 105 is formed, a third insulating dielectric layer 124 covering a top of the first interconnection structure 105 and covering the second insulating dielectric layer 103 is formed. The third insulating dielectric layer 124 may be formed by using the thin film deposition process, such as PVD, CVD, ALD, and Epitaxy.

With continued reference to FIG. 7, in some embodiments, after the third insulating dielectric layer 124 is formed, the third insulating dielectric layer 124 is patterned, and a first patterned region 144 and a second patterned region 154 are formed in the third insulating dielectric layer 124.

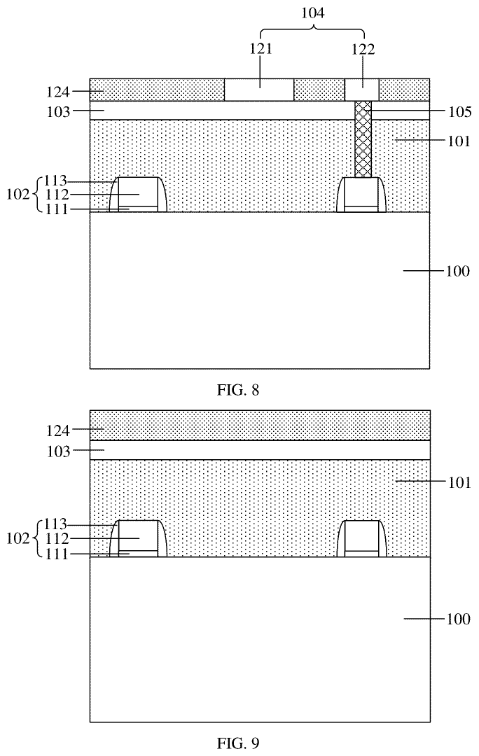

With continued reference to FIG. 8, after the first patterned region 144 and the second patterned region 154 are formed, the first conductive wire 121 and the first conductive wire 122 are correspondingly formed in the first patterned region 144 and the second patterned region 154 to complete the manufacturing of the current layer structure 104.

The process for forming the first conductive wire 121 and the first conductive wire 122 may be performed by deposition, electroplating, or other methods. After the thin film forming process, such as deposition or electroplating, is completed, the method further includes: performing a surface planarization process, and finally, forming the first conductive wires in the third insulating dielectric layer 124.

In some embodiments, the first interconnection structure 105 and the current layer structure 104 may be formed in the same process step. Specifically referring to FIG. 9, after the second insulating dielectric layer 103 is formed, the third insulating dielectric layer 124 is then deposited on the second insulating dielectric layer 103. For the processes of forming the second insulating dielectric layer 103 and the third insulating dielectric layer 124, reference may be made to the foregoing descriptions, and details are not described here again.

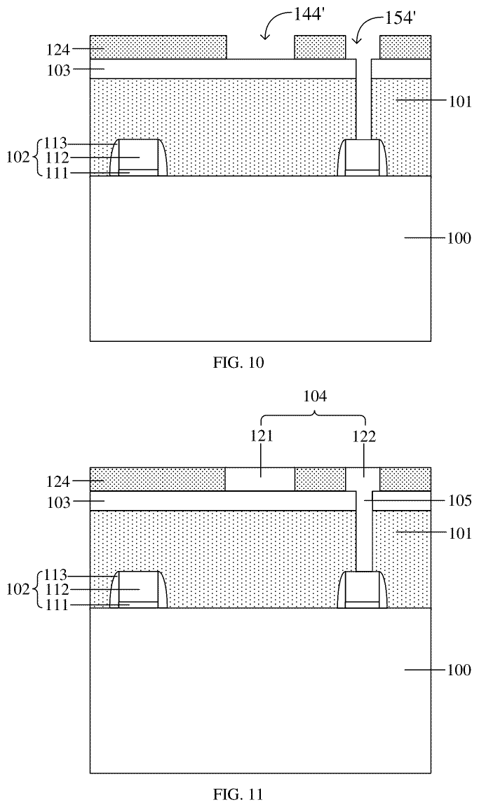

With continued reference to FIG. 10, after the third insulating dielectric layer 124 is formed, the third insulating dielectric layer 124, the second insulating dielectric layer 103, and the first insulating dielectric layer 101 are patterned to form a first patterned region 144′ and a second patterned region 154′. In some embodiments, the first patterned region 144′ and the second patterned region 154′ may be formed in different steps. That is, the first patterned region 144′ or the second patterned region 154′ is formed first, and then the second patterned region 154′ or the first patterned region 144′ is formed. That is, the first patterned region 144′ only needs to be formed in the third insulating dielectric layer 124, and the second patterned region 154′ is simultaneously formed in the third insulating dielectric layer 124, the second insulating dielectric layer 103, and the first insulating dielectric layer 101. The second patterned region 154′ may be formed by using, for example, a dual damascene process.

With continued reference to FIG. 11, after the first patterned region 144′ and the second patterned region 154′ are formed, a conductive material is deposited in each patterned region to form the first conductive wire 121, the first interconnection structure 105, and the first conductive wire 122 connected to the first interconnection structure 105. In this case, the first interconnection structure 105 and the first conductive wire 122 include the same conductive material.

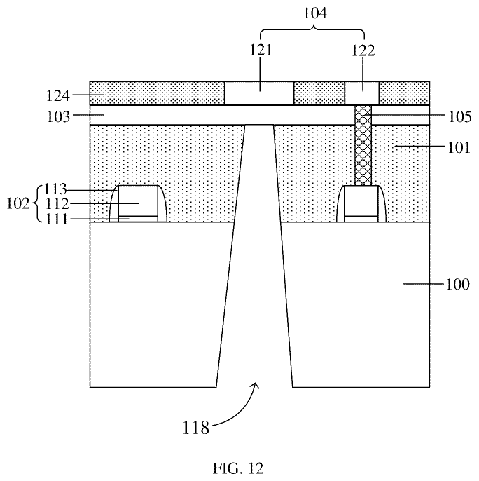

With continued reference to FIG. 12, after the third insulating dielectric layer 124 and the current layer structure 104 are formed, the substrate 100 and the first insulating dielectric layer 101 are etched in a direction from the substrate 100 toward the first insulating dielectric layer 101 to form an initial through hole 118. The initial through hole 118 exposes a surface, facing the first insulating dielectric layer 101, of the second insulating dielectric layer 103.

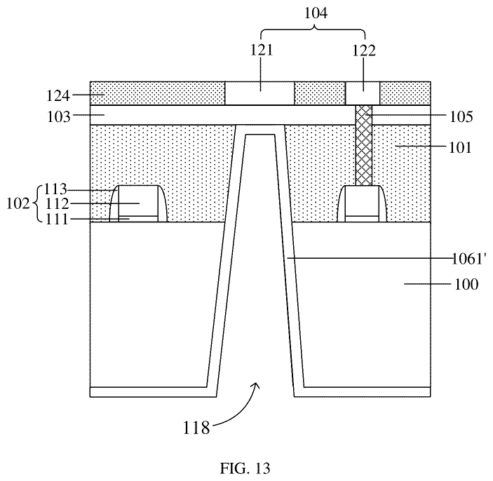

With continued reference to FIG. 13, after the initial through hole 118 is formed, an initial insulating liner layer 1061′ is formed on the substrate 100 and the surfaces of the first insulating dielectric layer 101 and the second insulating dielectric layer 103 that are exposed by the initial through hole 118 by using a thin film deposition process. A material of the initial insulating liner layer 1061′ may be silicon dioxide.

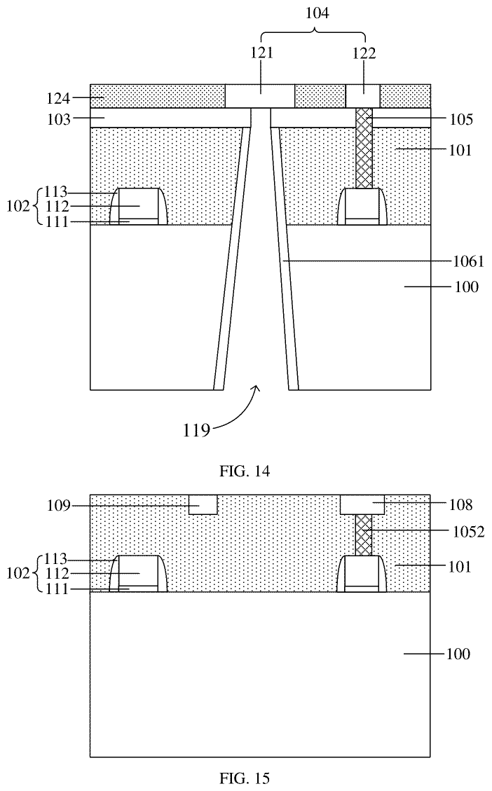

With continued reference to FIG. 14, after the initial insulating liner layer 1061′ is formed, the initial insulating liner layer 1061′ on the surface of the second insulating dielectric layer 103, as well as the initial insulating liner layer 1061′ on a side, distal to the first insulating dielectric layer 101, of the substrate 100, is etched and removed, while the initial insulating liner layer 1061′ located on the substrate 100 and the surface of the first insulating dielectric layer 101 is retained, thereby forming an insulating liner layer 1061. The insulating liner layer 1061 covers side walls of the initial through hole 118.

With continued reference to FIG. 14, after the insulating liner layer 1061 is formed, the second insulating dielectric layer 103 is further etched to expose a surface, facing the second insulating dielectric layer 103, of the first conductive wire 121 located in the third insulating dielectric layer 124, thereby forming a second through hole 119 that passes through the substrate 100, the first insulating dielectric layer 101, and the second insulating dielectric layer 103.

After the second through hole 119 is formed, a conductive interconnect layer 1062 is formed in the second through hole 119 by using a thin film forming process, such as deposition or electroplating, thereby forming a second interconnection structure 106 connected to the first conductive wire 121, and finally forming the semiconductor structure as shown in FIGS. 1 to 2.

In the above embodiments, the second insulating dielectric layer 103 serves as an etching stop layer for etching the first insulating dielectric layer 101; that is, the materials of the first insulating dielectric layer 101 and the second insulating dielectric layer 103 are selected to have a relatively high etching selectivity, avoiding etching into the first conductive wires in the process of etching the first insulating dielectric layer 101. This prevents metal ions in the first conductive wires from diffusing into the first insulating dielectric layer 101 and even the substrate 100, thereby preventing the first insulating dielectric layer 101 and the substrate 100 from being contaminated by the metal ions. When the first conductive wires are made of metal copper, controlling the risk posed by copper ion contamination is especially important.

When the second insulating dielectric layer 103 is etched to expose the first conductive wires to form the second through hole 119, due to the etching process, the surface of the first conductive wire may also be slightly damaged by the etching process, and metal ions may be brought out. Since the insulating liner layer 1061 has been formed on the exposed side walls of the first insulating dielectric layer 101 and the substrate 100 at this time, the metal ions that are brought out will not diffuse into the first insulating dielectric layer 101 and the substrate 100, thereby avoiding the risk posed by metal ion contamination.

In some embodiments, the front layer structure further includes, in addition to the transistor 102, a plurality of second conductive wires 108 and second conductive wires 109 that are isolated from each other. As shown in FIG. 15, the second conductive wires are formed in the first insulating dielectric layer 101, and the connection between the second conductive wire 108 and the transistor 102 is achieved by a second interconnection portion 1052.

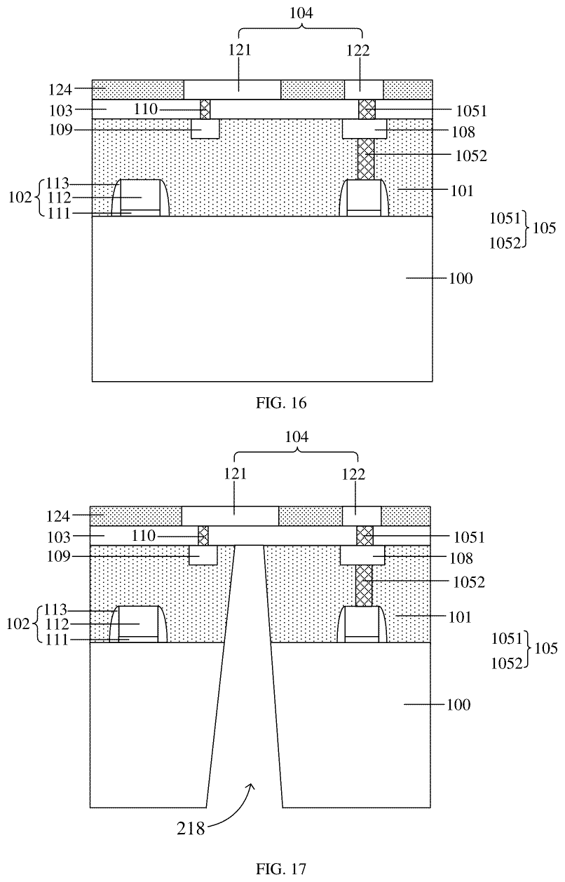

With continued reference to FIG. 16, after the second conductive wires are formed, a second insulating dielectric layer 103 covering the second conductive wires and a third insulating dielectric layer 124 are formed on the first insulating dielectric layer 101. Subsequently, a third interconnection structure 110 interconnected with the second conductive wires and a first interconnection portion 1051 interconnected with the second conductive wire 108 on the second interconnection portion 1052 are formed in the second insulating dielectric layer 103 and the third insulating dielectric layer 124. The first interconnection portion 1051 and the second interconnection portion 1052 form a first interconnection structure 105. The current layer structure 104 is also formed in the third insulating dielectric layer 124. The first conductive wire 121 in the current layer structure 104 is connected to the third interconnection structure 110, and the first conductive wire 122 in the current layer structure 104 is connected to the first interconnection portion 1051.

In some embodiments, the current layer structure 104, the third interconnection structure 110, and the first interconnection portion 1051 may be formed separately. That is, the second insulating dielectric layer 103 is deposited first, the first interconnection portion 1051 and the third interconnection structure 110 are formed in the second insulating dielectric layer 103, and then the third insulating dielectric layer 124 is deposited to form the current layer structure 104 in the third insulating dielectric layer 124.

In some embodiments, the current layer structure 104, the third interconnection structure 110, and the first interconnection portion 1051 may be formed simultaneously. That is, the second insulating dielectric layer 103 and the third insulating dielectric layer 124 are deposited first, and the first interconnection portion 1051, the third interconnection structure 110, and the first conductive wires connected respectively to the first interconnection portion 1051 and the third interconnection structure 110 are simultaneously formed in the second insulating dielectric layer 103 and the third insulating dielectric layer 124.

In some embodiments, the third interconnection structure 110 and the first interconnection portion 1051 further pass through a portion of the third insulating dielectric layer 124 and are interconnected with the respective first conductive wires. In this case, the forming processes of the first conductive wires, the third interconnection structure 110, and the first interconnection portion 1051 are the same as those described above, and details are not described here again.

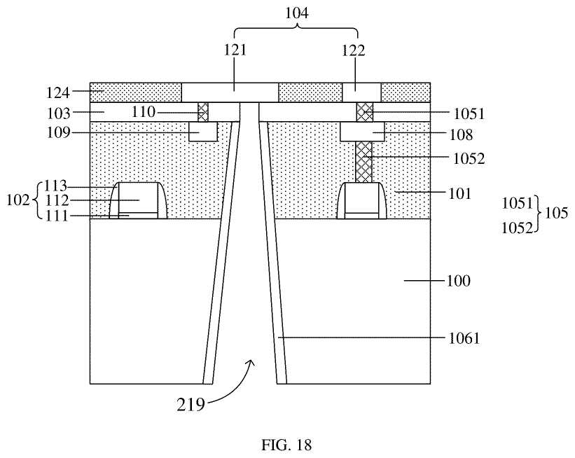

With continued reference to FIG. 17, after the structure shown in FIG. 16 is formed, the substrate 100 and the first insulating dielectric layer 101 are etched in a direction from the substrate 100 toward the first insulating dielectric layer 101 to form an initial through hole 218. The initial through hole 218 exposes a surface, facing the first insulating dielectric layer 101, of the second insulating dielectric layer 103.

With continued reference to FIG. 18, after the initial through hole 218 is formed, an insulating liner layer 1061 is formed on a surface of the substrate 100 and a surface of the first insulating dielectric layer 101 that are exposed, and the second insulating dielectric layer 103 is further etched to finally form a second through hole 219. The second through hole 219 exposes a surface of the first conductive wire 121.

When the second insulating dielectric layer 103 is etched to expose the first conductive wires to form the second through hole 219, due to the etching process, the surface of the first conductive wire may also be slightly damaged by the etching process, and metal ions may be brought out. Since the insulating liner layer 1061 has been formed on the exposed side walls of the first insulating dielectric layer 101 and the substrate 100 at this time, the metal ions that are brought out will not diffuse into the first insulating dielectric layer 101 and the substrate 100, thereby avoiding the risk posed by metal ion contamination.

After the second through hole 219 is formed, a conductive interconnect layer 1062 is formed in the second through hole 219 by using the thin film forming process, such as deposition or electroplating, thereby forming a second interconnection structure 106 connected to the first conductive wire 121, and finally forming the semiconductor structure as shown in FIGS. 3 to 4.

In the embodiments of the present disclosure, the second insulating dielectric layer 103 is formed first before the second interconnection structure 106 is formed, such that the second interconnection structure 106 can be prevented from contaminating the third insulating dielectric layer 124 in the current layer structure 104. Secondly, the first interconnection structure 105 is formed in the second insulating dielectric layer 103, the first interconnection structure 105 and the second interconnection structure 106 are separated by means of the first insulating dielectric layer 101 and the second insulating dielectric layer 103, such that the stress between the first interconnection structure 105 and the second interconnection structure 106 is alleviated by means of the first insulating dielectric layer 101 and the second insulating dielectric layer 103, thereby improving the reliability of the semiconductor structure.

In some embodiments, a material of the second insulating dielectric layer 103 may be different from a material of the first insulating dielectric layer 101, which can be beneficial for serving as an etching stop layer for etching the first insulating dielectric layer 101 in the process of forming the second interconnection structure 106, thereby preventing the formed second interconnection structure 106 from contaminating the third insulating dielectric layer 124 in the current layer structure 104.

It can be understood that a heat treatment process is usually involved in the process of forming the second interconnection structure 106. In the heat treatment process, the second interconnection structure 106 will undergo thermal expansion, thereby generating stress around the second interconnection structure 106. This stress is most concentrated at end parts of the second interconnection structure 106. By configuring the second insulating dielectric layer 103, the stress generated in the formation of the second interconnection structure 106 can also be alleviated.

Due to the heat treatment process involved in the process of forming the second interconnection structure 106, the second interconnection structure will undergo volume expansion. Generally, no other conductive structures are disposed around the second interconnection structure 106. The formation of the second insulating dielectric layer 103 alleviates the stress exerted by the second interconnection structure 106 on the surroundings, such that the spacing between the second interconnection structure 106 and the first interconnection structure 105 can be reduced, thereby helping to improve the integration level of the semiconductor structure.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

What is claimed is:

1. A semiconductor structure, comprising:
a substrate, wherein a first insulating dielectric layer is disposed on the substrate;
a front layer structure, wherein the front layer structure is disposed in the first insulating dielectric layer;
a second insulating dielectric layer, wherein the second insulating dielectric layer is disposed on the first insulating dielectric layer;
a third insulating dielectric layer, wherein the third insulating dielectric layer is disposed on the second insulating dielectric layer;
a current layer structure, wherein the current layer structure is disposed in the third insulating dielectric layer and comprises a plurality of first conductive wires spaced apart from each other;
a first interconnection structure, wherein the first interconnection structure passes through the second insulating dielectric layer and is connected to a portion of the plurality of first conductive wires and
the front layer structure; and
a second interconnection structure, wherein the second interconnection structure passes through the first insulating dielectric layer and the second insulating dielectric layer and is connected to
a portion of the first conductive wires; the first interconnection structure and the second interconnection structure are isolated from each other.

2. The semiconductor structure according to claim 1, wherein the second interconnection structure further penetrates through the substrate.

3. The semiconductor structure according to claim 1, wherein the first conductive wires cover
a top surface of the second insulating dielectric layer, and the first interconnection structure further passes through the first insulating dielectric layer and is connected to the front layer structure.

4. The semiconductor structure according to claim 1, wherein the first interconnection structure and the second interconnection structure
further pass through a portion of the third insulating dielectric layer and are respectively connected to the first conductive wires.

5. The semiconductor structure according to claim 1, wherein the front layer structure comprises a transistor, and the transistor
is connected to the first interconnection structure.

6. The semiconductor structure according to claim 5, wherein the front layer structure further comprises a plurality of second conductive wires, and
each of the plurality of second conductive wires is disposed in the first insulating dielectric layer above the transistor; the first interconnection structure comprises a first interconnection portion connecting a portion of the first conductive wires and a portion of the second conductive wires, and a second interconnection portion connecting a portion of the second conductive wires and the transistor, the first interconnection portion passing through the second insulating dielectric layer and being connected to the second conductive wire, and the second interconnection portion passing through the first insulating dielectric layer and being connected to the transistor.

7. The semiconductor structure according to claim 6, wherein the semiconductor structure further comprises a third interconnection structure; a portion of the second conductive wires is connected to the first interconnection structure, and a portion of the second conductive wires is connected to the third interconnection structure, the second conductive wire connected to the third interconnection structure being connected to the first conductive wire connected to the second interconnection structure via the third interconnection structure.

8. The semiconductor structure according to claim 1, wherein the second interconnection structure comprises an insulating liner layer and a conductive interconnect layer; the insulating liner layer is provided between the first insulating dielectric layer and the conductive interconnect layer, and the conductive interconnect layer is in direct contact with the second insulating dielectric layer.

9. The semiconductor structure according to claim 1, wherein the first interconnection structure and the second interconnection structure comprise different metals.

10. The semiconductor structure according to claim 4, wherein a ratio of a thickness of the second interconnection structure in the second insulating dielectric layer to a thickness of the second interconnection structure in the third insulating dielectric layer is 2:1 to 5:1.

11. The semiconductor structure according to claim 1, wherein the first insulating dielectric layer and the second insulating dielectric layer comprise different insulating materials.

12. A method for manufacturing a semiconductor structure, comprising:
providing a substrate, wherein a first insulating dielectric layer is disposed on the substrate;
forming a front layer structure, wherein the front layer structure is disposed in the first insulating dielectric layer;
forming a second insulating dielectric layer, wherein the second insulating dielectric layer is disposed on the first insulating dielectric layer;
forming a third insulating dielectric layer, wherein the third insulating dielectric layer is disposed on the second insulating dielectric layer;
forming a current layer structure, wherein the current layer structure is disposed in the third insulating dielectric layer and comprises a plurality of first conductive wires spaced apart from each other;
forming a first interconnection structure, wherein the first interconnection structure passes through the second insulating dielectric layer to connect a portion of the plurality of first conductive wires and the front layer structure; and
forming a second interconnection structure, wherein the second interconnection structure passes through the first insulating dielectric layer and the second insulating dielectric layer to connect a portion of the first conductive wires; the first interconnection structure and the second interconnection structure are isolated from each other.

13. The method for manufacturing a semiconductor structure according to claim 12, wherein a method for forming the first interconnection structure
comprises:
etching, after forming the second insulating dielectric layer and before forming the third insulating dielectric layer, at least the second insulating dielectric layer to form a first through hole abutting against the front layer structure; and
filling the first through hole to form the first interconnection structure.

14. The method for manufacturing a semiconductor structure according to claim 13, wherein a method for forming the current layer structure
comprises:
patterning, after forming the third insulating dielectric layer, the third insulating dielectric layer to form the plurality of first conductive wires in the third insulating dielectric layer, wherein a portion of the first conductive wires is connected to the first interconnection structure.

15. The method for manufacturing a semiconductor structure according to claim 12, wherein a method for forming the second interconnection structure
comprises:
etching, after forming the third insulating dielectric layer and the current layer structure, the substrate and the first insulating dielectric layer in a direction from the substrate toward the first insulating dielectric layer to form an initial through hole, the initial through hole exposing a surface of the second insulating dielectric layer;
forming an insulating liner layer, wherein the insulating liner layer covers side walls of the initial through hole;
etching at least the second insulating dielectric layer until a surface, facing the substrate, of a portion of the first conductive wires is exposed, to
form a second through hole exposing a portion of the first conductive wires; and
filling the second through hole to form a conductive interconnect layer, the conductive interconnect layer and the insulating liner layer forming the second interconnection structure.
